(19) United States
(12) Patent Application Publication
(10) Pub. No.: US 2010/0233616 A1
(43) Pub. Date: Sep. 16, 2010

(54) Method for producing plastic lens

(76) Inventors: Takaaki Kobayashi, Tokyo (JP); Masato Mikawa, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/308,659

(22) PCT Filed: Jun. 25, 2007
(86) PCT No.: PCT/JP2007/062666

§ 371 Date: Dec. 19, 2008

(30) Foreign Application Priority Data
Jun. 29, 2006 (JP) 2006-179679
Jun. 29, 2006 (JP) 2006-179689
Sep. 29, 2006 (JP) 2006-267045

(51) Int. Cl. G03F 7/004; G03F 7/20; B29D 11/00

(52) U.S. Cl. 430/270.1; 430/321; 264/1.32

(57) ABSTRACT

Disclosed is a method for producing a plastic lens having reflow heat resistance at 260° C., which is characterized in that a photosensitive resin composition containing a specific resin and a photopolymerization initiator is molded into a lens shape. The resin is obtained by mining one or more compounds (a) selected from the group consisting of (CH₃O)₃—Si—(CH₂)₃—O—CO—C(CH₃)═CH₂, (CH₃O)₃—Si—(CH₂)₃—O—CO—CH═CH₂, (CH₃O)₃—Si—(CH₂)ₓ—CH═CH₂ (wherein X is 1 or 2), (CH₃O)₂—Si(CH₃)(CH₂)₃—O—CO—C(CH₃)═CH₂, (CH₃O)₂—Si(CH₃)(CH₂)₃—O—CO—CH═CH₂ and (CH₃O)₂—Si(CH₃)—(CH₂)ₓ—CH═CH₂ (wherein X is 1 or 2) with a compound (b) represented by (C₆H₅)₂—Si—(OH)₂ such that 50-150 moles of the compounds (a) is mixed per 100 moles of the compound (b), and then polycondensing the mixture at 40-15° C. for 0.1-10 hours in the presence of a catalyst.

### TECHNICAL FIELD

The present invention relates to a method for producing a plastic lens which is intended to be applied mainly to optical uses. More particularly, it relates to a method for producing a plastic lens for solid-state image sensing devices such as, typically, microplastic lenses for optical communication and CMOS image sensors. The term “microplastic lens” or “minilens” is used when the size of the plastic lens is small.

### BACKGROUND ART

Plastic lenses are widely used for various optical articles as they are easier to mold and lower in cost than glass lenses. Various transparent materials, for example, thermoplastics such as polymethyl methacrylate and polystyrene and thermosetting plastics such as polydiethylene glycol bisallylcarbonate are used as materials for plastic lenses.

The conventional materials, however, as shown in Patent Documents 1 and 2, are mostly limited in heat resistance to temperatures of up to 200° C., even in their improved version, and are unable to measure up to the requirement for solder reflow heat resistance at 260° C.

The siloxane resins having an Si—O structure are generally high in heat resistance. In Patent Documents 3 and 4, the UV curing siloxane resins are introduced as a wear-resistant hard coating material. Any of these resins, however, is restricted to use as a thin film coating material. In general, the siloxane resins, although excellent in heat resistance, are poor in crack resistance, so that they have the problem that they are difficult to serve as a thick-film structural material.

Patent Document 5 discloses a material known as ORMOCER ONE (produced by Fraunhofer ISC, Germany) produced by subjecting an organosilane having a polymerizable group and an organosilane having a hydrolysis reaction point to polycondensation by using barium hydroxide (Ba(OH)₂) as a catalyst. This material is capable of curing at a temperature as low as 150° C. and has heat resistance at 300° C. or higher. The problem with this material is that it is poor in adhesion to the dissimilar base materials (metal, glass, silicon, etc.).

Patent Documents 6, 7 and 8 disclose a process of forming the microlens array for the liquid crystal projectors. According to this process, a UV curing transparent resin is pressed into a metal mold by a transparent glass substrate, and exposed to ultraviolet light through the glass substrate to cure the transparent resin for a lens. In this process, however, if the resin is poorly adhesive to the substrate, the resin pattern tends to fail to form thereon in the releasing step after radiation curing, leaving the resin in the mold. This is a serious problem with this process.

Patent Document 9 teaches a method for improving adhesion of a transparent resin to a glass substrate, according to which the resin is initially coated as a thin film on its surface and then irradiated once with ultraviolet light over the whole surface to form a cured film. This method, however, is unsatisfactory for providing the desired improvement of adhesion.

On the other hand, regarding the method for forming a plastic lens without using a mold, Patent Document 10 discloses a method for forming a heat resistant microlens on a solid-state image sensor by an optical exposure system using a mask or a thermal melting system. This patent, however, discloses only positive type resin materials and further has the problem that the heat resistance temperature of such positive type materials is 200° C. or lower. As another example of the optical exposure system using a mask, Patent Document 11 discloses a method using a semitransparent mask having a lenticular light intensity profile. In this patent, however, there are disclosed only the positive type photosensitive resin materials, and the formed lens pattern is heat resistant at 200° C. or lower. Also, in order to enhance heat resistance, it was necessary to conduct dry etching on the glass base. Accordingly, the lens molding process has the problem that it is complicated, and requires a costly processing facility.

### Patent Document 1: JP-A-09-31136

### Patent Document 2: JP-A-2004-245867

### Patent Document 3: JP-A-03-281616

### Patent Document 4: WO 2002/102907 A

### Patent Document 5: Canadian Patent No. 2378756

### Patent Document 6: JP-A-10-253801

### Patent Document 7: JP-A-2001-194508

### Patent Document 8: JP-A-01-257901

### Patent Document 9: JP-A-05-249302

### Patent Document 10: JP-A-06-138306

### Patent Document 11: JP-A-2001-158022

### DISCLOSURE OF THE INVENTION

### Problems to be Solved by the Invention

The present invention aims at providing a plastic lens having reflow heat resistance at 260° C., and a method for producing such a lens.

### Means for Solving the Problems

In the course of studies on the photosensitive resins containing a siloxane for solving the above problem, the present inventor has succeeded in completing the present invention which comprises molding a specific photosensitive resin composition into a lens shape. The present invention is embodied as follows.

(1) A method for producing a plastic lens characterized in that a photosensitive resin composition containing a resin and a photopolymerization initiator is molded into a lens shape, the resin being obtained by mixing at least one compound (a) selected from the group consisting of (CH₃O)₃—Si—(CH₂)₃—O—CO—C(CH₃)—CH₂, (CH₃O)₃—Si—(CH₂)₃—O—CO—CH═CH₂, (CH₃O)₃—Si—(CH₂)ₓ—CH═CH₂ (wherein X is 1 or 2), (CH₃O)₂—Si(CH₃)(CH₂)₃—O—CO—C(CH₃)═CH₂, (CH₃O)₂—Si(CH₃)(CH₂)₃O—CO—CH═CH₂, and (CH₃O)₂—Si(CH₃)—(CH₂)ₓ—CH═CH₂ (wherein X is 1 or 2)
with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst.
(2) A method for producing a plastic lens characterized by comprising a first step comprising a process of filling in a plastic lens mold having an opening(s) a photosensitive resin composition containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—Si—(CH₂)₃—O—CO—CH═CH₂, (CH₃O)₃—Si—(CH₂)ₓ—CH═CH₂ (wherein X is 1 or 2), (CH₃O)₂—Si (CH₃) (CH₂)₃—O—CO—C(CH₃)═CH₂, (CH₃O)₂—Si(CH₃)(CH₂)₃—O—CO—CH═CH₂, and (CH₃O)₂—Si(CH₃)—(CH₂)ₓ—CH═CH₂ (wherein X is 1 or 2) with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst, and a process of pressing against a substrate the opening(s) of the mold filled with the photosensitive resin composition; a second step of exposing the photosensitive resin composition to light; a third step of separating the mold from the substrate; and a fourth step of heating the exposed photosensitive resin composition at a temperature of 150° C. to 250° C. for 0.5 hour to 2 hours, the first to fourth steps being carried out sequentially.
(3) The method for producing a plastic lens according to (2) characterized in that the first step is a first step comprising a process of coating a substrate with a silane compound or a composition containing a silane compound to obtain a substrate having a silane compound deposited thereon, a process of filling in the plastic lens mold having an opening(s) the photosensitive resin composition containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—S—(CH₂)₃—O—CO—CH═CH₂, (CH₃O)₃—Si—(CH₂)ₓ—CH═CH₂ (wherein X is 1 or 2), (CH₃O)₂—Si (CH₃)(CH₂)₃—O—CO—C(CH₃)═CH₂, (CH₃O)₂—Si(CH₃)(CH₂)₃—O—CO—CH═CH₂ and (CH₃O)₂—Si(CH₃)—(CH₂)ₓ—CH═CH₂ (wherein X is 1 or 2)
with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst, and a process of pressing the opening(s) of the mold filled with the photosensitive resin composition against the silane compound-deposited side of the substrate.
(4) The method for producing a plastic lens according to (3) characterized in that the composition containing a silane compound is a composition same as the above photosensitive resin composition.
(5) The method for producing a plastic lens according to (3) or (4) characterized in that the photosensitive resin composition is a photosensitive resin composition containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—Si—(CH₂)₃—O—CO—CH═CH₂, (CH₃O)₃—Si—(CH₂)ₓ—CH═CH₂ (wherein X is 1 or 2) with a compound (b) represented by (C₆H₅)₂—Si—(OH)₂ in a molar ratio of (a)/(b) of 60 mole %/40 mole % to 40 mole %/60 mole %, and then subjecting the mixture to polycondensation at a temperature of 40° C. to 150° C. for 0.1 to 10 hours in the presence of a catalyst.
(6) The method for producing a plastic lens according to (3) or (4) characterized in that the photosensitive resin composition is a photosensitive resin composition containing a resin and a photopolymerization initiator, the resin being obtained by mixing at least one compound (a-1) selected from the group consisting of (CH₃O)₃—Si—(CH₂)₃—O—CO—C(CH₃)═CH₂, (CH₃O)₃—Si—(CH₂)₃—O—CO—CH═CH₂ and (CH₃O)₃—Si—(CH₂)ₓ—CH═CH₂ (wherein X is 1 or 2) and at least one compound (a-2) selected from the group consisting of (CH₃O)₂—Si(CH₃)(CH₂)₃—O—CO—C(CH₃)═CH₂, (CH₃O)₂—Si(CH₃)(CH₂)₃—O—CO—CH═CH₂, and (CH₃O)₂—Si(CH₃)—(CH₂)ₓ—CH═CH₂ (wherein X is 1 or 2) with a compound (b) represented by (C₆H₅)₂—Si—(OH)₂ in a proportion of 10 to 60 moles of the compound (a-1) and 40 to 90 moles of the compound (a-2) based on 100 moles of the compound (b), and then subjecting the mixture to polycondensation at a temperature 40° C. to 150° C. for 0.1 to 10 hours in the presence of a catalyst.
(7) A method for producing a plastic lens characterized by comprising a step of coating a substrate with a photosensitive resin composition containing a resin and a photopolymerization initiator, the resin being obtained by mixing at least one compound (a) selected from the group consisting of (CH₃O)₃—Si—(CH₂)₃O—CO—C(CH₃)═CH₂, (CH₃O)₃—Si—(CH₂)₃—O—CO—CH═CH₂, and (CH₃O)₃—Si—(CH₂)ₓ—CH═CH₂(wherein X is 1 or 2) with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst, and heating the coated substrate at 50 to 150° C. for one minute to 30 minutes to obtain a substrate having a photosensitive resin composition deposited thereon; a step of laying on the substrate one of a plurality of masks which form a concentric pattern when placed one on another, and then exposing it at a constant light intensity given by

(the lowest light intensity causing saturation of resin film thickness retained after resin removal by development)÷(number of masks), and then removing the mask, a series of these operations being conducted once for each mask to thereby effect multiple exposure; a step of development; and a step of heating at a temperature of 150° C. to 250° C. for 0.5 hour to 2 hours, these steps being carried out sequentially.

(8) A photosensitive resin composition for forming a plastic lens containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—S(CH₂)₃—O—CO—CH═CH₂, (CH₃O)₃—Si—(CH₂)ₓ—CH═CH₂ (wherein X is 1 or 2), (CH₃O)₂—Si (CH₃)(CH₂)₃—O—CO—C(CH₃)═CH₂, (CH₃O)₂—Si(CH₃)(CH₂)₃—O—CO—CH═CH₂, and (CH₃O)₂—Si(CH₃)—(CH₂)ₓ—CH═CH₂(wherein X is 1 or 2) with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst.
(9) A plastic lens obtained by radiation curing a photosensitive resin composition containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—Si—(CH₂)₃—O—CO—CH═CH₂, (CH₃O)₃—Si—(CH₂)ₓ—CH═CH₂ (wherein X is 1 or 2), (CH₃O)₂—Si(CH₃)(CH₂)₃—O—CO—C(CH₃)═CH₂, (CH₃O)₂—Si(CH₃)(CH₂)₃—O—CO—CH═CH₂ and (CH₃O)₂—Si(CH₃)—(CH₂)ₓ—CH═CH₂ (wherein X is 1 or 2) with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst.

### ADVANTAGE OF THE INVENTION

According to the present invention, it is possible to produce a plastic lens having solder reflow resistance at 260° C.

### BEST MODE FOR CARRYING OUT THE INVENTION

### (1) Photosensitive Resin Composition

The photosensitive resin composition of the present invention is a photosensitive resin composition containing a resin and a photopolymerization initiator, the resin being obtained by mixing one or more compounds (a) selected from the group consisting of (CH₃O)₃—Si—(CH₂)₃—O—CO—C(CH₃)═CH₂ (CH₃O)₃—Si—(CH₂)₃—O—CO—CH═CH₂, (CH₃O)₃—Si—(CH₂)ₓ—CH═CH₂ (wherein X is 1 or 2), (CH₃O)₂—Si (CH₃)(CH₂)₃—O—CO—C(CH₃)═CH₂, (CH₃O)₂—Si(CH₃)(CH₂)₃—O—CO—CH═CH₂, and (CH₃O)₂—Si (CH₃)— (CH₂)ₓ—CH═CH₂ (wherein X is 1 or 2)

with a compound (b) represented by (C₆H₅)₂—Si—(H)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst.

The compound designated by (a) is one or more compounds selected from the group consisting of (CH₃O)₃—Si—(CH₂)₃—O—CO—C(CH₃)═CH₂, (CH₃O)₃—Si—(CH₂)₃—O—CO—CH═CH₂, (CH₃O)₃—Si—(CH₂)ₓ—CH═CH₂ (wherein X is 1 or 2), (CH₃O)₂—Si(CH₃)(CH₂)₃—O—CO—C(CH₃)═CH₂, (CH₃O)₂—Si(CH₃)(CH₂)₃—O—CO—CH═CH₂, and (CH₃O)₂—Si (CH₃)— (CH₂)ₓ—CH═CH₂ (wherein X is 1 or 2). Preferred among these compounds are 3-methacryloxypropyltrimethoxysilane (which may hereinafter be referred to as MEMO) represented by the following general formula (I) and 3-methacryloxypropylmethyldimethoxysilane (which may hereinafter be referred to as MEDMO) represented by the following general formula (II).

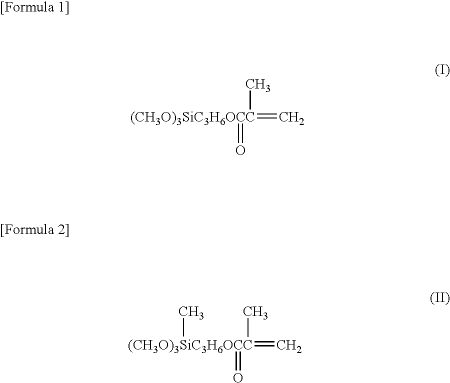

The compound designated by (b) is (C₆H₅)₂—Si—(OH)₂, or diphenylsilanediol (which may hereinafter be referred to as DPD).

The molar ratio of the compound (a) per 100 moles of the compound (b) is preferably 82 to 122. It is preferable from the viewpoint of pyrolytic heat resistance that the compound (a) is one or more compounds selected from the group consisting of (CH₃O)₃—Si—(CH₂)₃—O—CO—C(CH₃)═CH₂, (CH₃O)₃—Si—(CH₂)₃—O—CO—CH═CH₂ and (CH₃O)₃—Si—(CH₂)ₓ—CH═CH₂ (wherein X is 1 or 2).

In this case, the mixing ratio by mol % of the compound (a) to the compound (b) is preferably 60 mole %/40 mole % to 40 mole %/60 mole %, more preferably 55 mole %/45 mole % to 45 mole %/55 mole %, even more preferably 52 mole %/48 mole % to 48 mole %/52 mole %, most preferably 50 mole %/50 mole %.

It is also preferable from the viewpoint of thermal shock resistance that the photosensitive resin composition is a photosensitive resin composition containing a resin and a photopolymerization initiator, the resin being obtained by mixing one or more compounds (a-1) selected from the group consisting of (CH₃O)₃—Si—(CH₂)₃—O—CO—C(CH₃)═CH₂, (CH₃O)₃—Si—(CH₂)₃—O—CO—CH═CH₂ and (CH₃O)₃—Si—(CH₂)ₓ—CH═CH₂ (wherein X is 1 or 2), and one or more compounds (a-2) selected from the group consisting of (CH₃O)₂—Si (CH₃)(CH₂)₃—O—C(CH₃)═CH₂, (CH₃O)₂—Si (CH₃)(CH₂)₃—O—CO—CH═CH₂, and (CH₃O)₂—Si(CH₃)—(CH₂)ₓ—CH═CH₂ (wherein X is 1 or 2) with a compound (b) represented by (C₆H₅)₂—Si—(OH)₂ in a proportion of 10 to 60 moles of the compounds (a-1) and 40 to 90 moles of the compounds (a-2) based on 100 moles of the compound (b), and then subjecting the mixture to polycondensation at a temperature of 40° C. to 150° C. for 0.1 to 10 hours in the presence of a catalyst. Of these compounds, MEMO is preferred as the compound (a-1), MEDMO is preferred as the compound (a-2), and DPD is preferred as the compound (b).

The temperature in the process for obtaining a resin by subjecting the mixture to polycondensation is 40 to 150° C., preferably 50 to 90° C., more preferably 70 to 90° C. From the viewpoint of polycondensation reactivity, the temperature should be 40° C. or higher, and from the view point of protection of the functional groups, the temperature should be 150° C. or lower. The time of this process is 0.1 to 10 hours, preferably 0.5 to 5 hours, more preferably 0.5 to 3 hours. From the viewpoint of polycondensation reactivity, the time of the process should be 0.1 hour or longer, and from the viewpoint of protection of the functional groups, the time of the process should be 10 hours or shorter.

In the above process for obtaining a resin by polycondensation of the mixture, a catalyst is used with no need of positive addition of water. Trivalent or tetravalent metal alkoxides can be used as the catalyst.

Examples of such metal alkoxides include trimethoxyaluminum, triethoxyaluminum, tri-n-propoxyaluminum, tri-iso-propoxyaluminum, tri-n-butoxyaluminum, tri-iso-butoxyaluminum, tri-sec-butoxyaluminum, tri-tert-butoxyaluminum, trimethoxyboron, triethoxyboron, tri-n-propoxyboron, tri-iso-propoxyboron, tri-n-butoxyboron, tri-iso-butoxyboron, tri-sec-butoxyboron, tri-tert-butoxyborontetramethoxysilane, tetraethoxysilane, tetra-n-propoxysilane, tetra-iso-propoxysilane, tetra-n-butoxysilane, tetra-iso-butoxysilane, tetra-sec-butoxysilane, tetra-tert-butoxysilane, tetramethoxygermanium, tetraethoxygermanium, tetra-n-propoxygermanium, tetra-iso-propoxygermanium, tetra-n-butoxygermanium, tetra-iso-butoxygermanium, tetra-sec-butoxygermanium, tetra-tert-butoxygermanium, tetramethoxytitanium, tetraethoxytitanium, tetra-n-propoxytitanium, tetra-iso-propoxytitanium, tetra-n-butoxytitanium, tetra-iso-butoxytitanium, tetra-sec-butoxytitanium, tetra-tert-butoxytitanium, tetramethoxyzirconium, tetraethoxyzirconium, tetra-n-propoxyzirconium, tetra-iso-propoxyzirconium, tetra-n-butoxyzirconium, tetra-iso-butoxyzirconium, tetra-sec-butoxyzirconium, and tetra-tert-butoxyzirconium. It is also possible to use barium hydroxide, sodium hydroxide, potassium hydroxide, strontium hydroxide, calcium hydroxide and magnesium hydroxide as a catalyst. Of these compounds, barium hydroxide, tetra-tert-butoxytitanium and tetra-tert-propoxytitanium are preferable. In order to realize rapid and uniform proceeding of the polymerization reaction, it is preferable that the catalyst be liquid in the reaction temperature region. The catalyst is fed in an amount of preferably 0.01 to 5 moles, more preferably 0.1 to 3 moles per 100 moles of the compound (b).

As a photopolymerization initiator contained in the photosensitive resin composition, the known photopolymerization initiators showing absorption at 365 nm, for example 2-benzyl-2-dimethylamino-4′-morpholinobutyrophenone (IRGACURE 369), can be used favorably. Other known photopolymerization initiators usable here include, for example, benzophenone, 4,4′-diethylaminobenzophenone, diethylthioxanethone, ethyl-p-(N,N-dimethylaminobenzoate), and 9-phenylacridine. A photopolymerization initiator is added in an amount of preferably 0.01 to 5 parts by weight, more preferably 0.3 to 3 parts by weight, particularly preferably 0.5 to 2 parts by weight per 100 parts by mass of the resin obtained by the polycondensation.

In the photosensitive resin composition, one or more compounds selected from the group consisting of a polyalkylene oxide di(meth)acrylate containing bisphenol A in the backbone and a polyalkylene oxide di(meth)acrylate may be added when a photopolymerization initiator is added or around that time. Here, the expression “(meth)acrylate” is used to refer to either acrylate or methacrylate. The same holds true in the following descriptions.

Addition of one or more compounds selected from the group consisting of a polyalkylene oxide di(meth)acrylate containing bisphenol A in the backbone and a polyalkylene oxide di(meth)acrylate produces an additional effect to improve thermal shock resistance.

The polyalkylene oxide moiety of the polyalkylene oxide di(meth)acrylate containing bisphenol A in the backbone includes polyethylene oxide, polypropylene oxide or polytetramethylene oxide. Among them, polyethylene oxide dimethacrylates containing bisphenol A in the backbone are preferred. Typical examples of such dimethacrylates are heat-resistant Blemmer PDBE-200, 250, 450 and 1300 represented by the following formula, which are commercially available from Nippon Oil Corp.

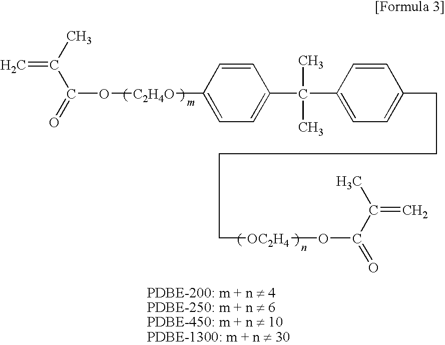

As the polyalkylene oxide moiety of the polyalkylene oxide di(meth)acrylates, polyethylene oxide, polypropylene oxide and polytetramethylene oxide can be cited as examples. Among them, polytetramethylene oxide dimethacrylates (with tetramethylene oxide recurring units of 5 to 10) are preferred, a typical example of which is Blemmer PDT 650 represented by the following formula, available from Nippon Oil Corp.

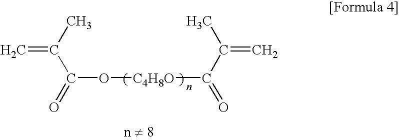

In case where one or more compounds selected from the group consisting of polyalkylene oxide di(meth)acrylate containing bisphenol A in the back bone and a polyalkylene oxide di(meth)acrylate are incorporated in the composition, their content in the composition is 1 to 30 parts by weight, preferably 5 to 20 parts by weight, more preferably 7 to 14 parts by weight, per 100 parts by weight of the resin obtained by subjecting the compound (a) and the compound (b) to polycondensation. Their content of 30 parts by weight or less is preferable because of high stability of the resin solution and low variation of product quality.

The present invention is a method for producing a plastic lens characterized in that the above-described photosensitive resin composition is molded into a lens shape. As the method for producing a plastic lens by molding a photosensitive resin composition into a lens shape, there are available, for example, “(2) a method for producing a microplastic lens utilizing a mold” and “(3) a method for producing a microplastic lens using masks” which are explained below in detail.

### (2) Method for Producing a Microplastic Lens Utilizing a Mold

A plastic lens can be produced by carrying out the following steps successively. Each step will be described by referring to FIG. 1.

First Step: step comprising a process of filling a plastic lens mold (1) having an opening(s) with the above-described photosensitive resin composition (FIG. 1 (a)), and a process of pressing against a substrate (3) the opening(s) of the mold filled with the photosensitive resin composition (FIG. 1 (b)):

First, a mold for a plastic lens having an opening(s) is provided. As the mold material, for instance, rubber, glass, plastic or a metal is used. In the case of a metal mold, it is preferably made of nickel.

The first step comprises a step of filling the mold with the photosensitive resin composition by using, for instance, a dropping pipette or a dispenser, and a process of pressing against a substrate the opening(s) of the mold filled with the photosensitive resin composition. The substrate is preferably made of glass for allowing passage of exposure light in the exposure step to be described later. In case where the mold is made of quartz, however, a silicon substrate may be used as exposure light can be passed through the mold.

Second Step: Step for Exposing the Photosensitive Resin Composition (FIG. 1 (c)):

The photosensitive resin composition is irradiated with ultraviolet light in a state where the photosensitive resin composition is sandwiched between the substrate and the mold. In case where a glass substrate is used, exposure is made through the glass substrate. In view of pattern resolution and convenience for handling as a radiation curing resin, i line is preferable for the irradiation light source wavelength, and a near exposure type projection aligner is preferably used for this process.

Third Step: Step for Separating the Plastic Lens from the Substrate (FIG. 1 (d)):

The plastic lens mold is separated from the substrate after UV curing.

### Fourth Step: Step for Heating the Exposed Photosensitive Resin Composition at a Temperature of 150° C. to 250° C. for 0.5 Hour to 2 Hours:

Heating at 150° C. to 250° C. for 0.5 hour to 2 hours causes bonding of the residual methacrylic groups, making it possible to obtain a plastic lens with excellent heat resistance. Heating can be conducted by a hot plate, an oven or a programmable temperature-rising oven. When a heating conversion is made, air may be used as an atmosphere gas. It is also possible to use inert gases such as nitrogen and argon.

It is preferable in view of adhesion of the plastic lens to the substrate that the first step includes a process of coating the substrate with a silane compound or a composition containing a silane compound to obtain a substrate having a silane compound deposited thereon, and that the process of pressing against the substrate the opening(s) of the mold filled with the photosensitive resin composition be a process in which the opening(s) of the mold filled with the photosensitive resin composition is pressed against the silane compound-deposited side of the substrate.

Coating of the substrate with a silane compound or a composition containing a silane compound is carried out by applying a silane compound or a composition containing a silane compound on the substrate by, for example, a spin coater, a bar coater, a blade coater, a curtain coater or a screen printer, or by spray coating with a spray coater, after properly diluting the compound or the composition with a solvent such as γ-butyrolactone, N-methylpyrrolidone (NMP), tetrahydrofuran (THF) or an alcohol with a carbon number of 1 to 6 or so. By this operation, a thin film of a silane compound or a composition containing a silane compound is formed. Thickness of this thin film is preferably 0.1 to 10 μm, more preferably 0.5 to 5 μm, even more preferably 1 to 3 μm.

It is preferable for the enhancement of adhesion to heat the substrate after having coated the substrate with a silane compound or a composition containing a silane compound. This heating is conducted with the silane compound-deposited side of the substrate facing upward. As a device for heating, it is possible to use any of the known heating devices such as an oven, a far-infrared oven and a hot plate, but a hot plate is preferred for providing enhanced adhesion between the substrate and a silane compound or a composition containing a silane compound. Heating is carried out at a temperature in the range of 50° C. to 150° C., preferably 100° C. to 140° C., for 1 minute to 30 minutes, preferably 5 minutes to 10 minutes.

The silane compounds to be used include, for example, 3-methacryloxypropyltrimethoxysilane, 3-acryloxypropyltrimethoxysilane, 3-glycidyloxypropyltrimethoxysilane, 2-(3,4-epoxycyclohexyl)ethyltrimethoxysilane, p-styryltrimethoxysilane, 3-methacryloxypropyltriethoxysilane, 3-acryloxypropyltriethoxysilane, 3-glycidyloxypropyltriethoxysilane, 2-(3,4-epoxycyclohexyl)ethyltriethoxysilane, p-styryltriethoxysilane, 3-methacryloxypropylmethyldimethoxysilane, 3-acryloxypropylmethyldimethoxysilane, 3-glycidyloxypropylmethyldimethoxysilane, 3-methacryloxypropylmethyldiethoxysilane, 3-acryloxypropylmethyldiethoxysilane, and 3-glycidyloxypropylmethyldiethoxysilane. As the compositions containing a silane compound, the above-mentioned photosensitive resin compositions can be used.

As the silane compound or the composition containing a silane compound, 3-methacryloxypropyltrimethoxysilane is preferable in terms of higher adhesion and convenience for handling. The above-mentioned photosensitive resin compositions are preferable for providing further enhancement of adhesion.

### (3) Method for Producing a Plastic Lens Using Masks

A plastic lens can be produced by carrying out the following steps successively.

Each step is explained with reference to FIG. 2.

In the first step, the photosensitive resin composition (4) is coated on a substrate (5) and heated at 50 to 150° C. for 1 minute to 30 minutes to obtain a substrate having the photosensitive resin composition deposited thereon (FIG. 2 (a)). The photosensitive resin composition is diluted with a solvent, for example, NMP, and then coated on the substrate by applying the composition with, for example, a spin coater, a bar coater, a blade coater, a curtain coater or a screen printer, or by spray coating with a spray coater to form a thin film of the photosensitive resin composition. Thickness of this thin film is preferably 1 to 30 μm, more preferably 2 to 10 μm, even more preferably 3 to 6 μm.

As the substrate, a glass substrate or a silicon substrate can be used.

Heating is conducted with the thin film coated side of the substrate coated with the photosensitive resin composition facing upward. As a device for heating, it is possible to use any of the known heating devices such as an oven, a far-infrared oven and a hot plate, but a hot plate is preferred for providing enhanced adhesion between the substrate and the photosensitive resin composition. Heating is carried out at a temperature in the range of 50° C. to 150° C., preferably 100° C. to 140° C., for 1 minute to 30 minutes, preferably 5 minutes to 10 minutes.

Step of laying on the substrate one of a plurality of masks (6) which form a concentric pattern when placed one on another, and then exposing it at a constant light intensity given by (the lowest light intensity causing saturation of resin film thickness retained after resin removal by development) (number of masks), and then removing the masks, with this series of operations being conducted once for each mask to thereby effect multiple exposure (FIGS. 2 (b-1) to (b-4)):

For example, here is shown a method in which the photosensitive resin composition is exposed by using 3 masks and then formed into a plastic lens shape. First, there are provided 3 masks which form a concentric circular pattern when placed one on another. One of these masks is laid on the substrate having the photosensitive resin composition deposited thereon obtained in the previous step, and exposed at a light intensity given by (the lowest light intensity causing saturation of resin film thickness retained after resin removal by development÷number of masks) (for instance, light intensity of 90 mJ/cm²÷3=30 mJ/cm²) by using an alignment mark, and then the mask is removed, with this process of operation being conducted once for each mask (FIGS. 2 (b-1) to (b-3)). Exposure may be started from any one of the masks, namely the operations (b-1) to (b-3) may be conducted in any order. FIG. 2 (b-4) shows a view taken from above the masks for forming a lens. Because of use of an alignment mark, the masks agree with each other at the center of the circle.

The above-mentioned “the lowest light intensity causing saturation of resin film thickness retained after resin removal by development” has the following meaning.

When the coating film of the photosensitive resin composition obtained by coating the photosensitive resin composition on the substrate is exposed, retention of the film after curing after development varies in accordance with the light intensity.

The lowest light intensity causing saturation of resin film thickness retained after resin removal by development is determined, for instance, from the graph of FIG. 3.

From a graph drawn up by plotting the light intensity from the exposure device as ordinate and the retained film thickness after development at that time as abscissa, it is found that the retained film thickness reaches saturation at around 2.5 μm.

“Saturation” indicates a point at which the variation of film thickness (delta thickness) is 0.1 μm or less when light intensity is increased stepwise by an increment of 20 mJ/cm².

It is seen from the graph of Table 1 that the lowest light intensity at this point is 100 mJ/cm².

This lowest light intensity (for instance, 100 mJ/cm²) is called “the lowest light intensity causing saturation of resin film thickness retained after resin removal by development.”

For the development in the step of development, any appropriate one of the known photoresist developing methods, such as rotational spraying, paddling or immersion assisted by sonication, can be used. The substrate after development is shown in FIG. 2 (c).

As the developer used in this step, a combination of a good solvent and a poor solvent for the photosensitive resin composition is preferable. Examples of the good solvents usable here include N-methylpyrrolidone, N-acetyl-2-pyrrolidone, N,N′-dimethylacetamide, cyclopentanone, cyclohexanone, γ-butyrolactone, α-acetyl-γ-butyrolactone, and methyl isobutyl ketone. Examples of the poor solvents include toluene, xylene, methanol, ethanol, isopropyl alcohol and water. The ratio of a poor solvent to a good solvent is adjusted in conformity to the solubility of the photosensitive resin composition. Combinations of these solvents are also usable.

Step of Heating at a Temperature of 150° C. to 250° C. for 0.5 Hour to 2 Hours after Development:

By heating at a temperature of 150° C. to 250° C. for 0.5 hour to 2 hours, the residual methacrylic groups can be bonded to provide a plastic lens and an optical element for liquid crystal polarizers with excellent heat resistance. Heating can be performed by a hot plate, an oven or a programmable temperature-rising oven. Air may be used as an atmosphere gas for heating conversion. Inert gases such as nitrogen and argon are also usable.

### EXAMPLES

The present invention is described in more detail with reference to the examples thereof, but it should be understood that these examples are not restrictive to the scope of the present invention.

### [Preparation of Photosensitive Resin Composition 1]

Into a 500 ml egg-plant type flask, MEMO was supplied as a compound (a) in an amount of 0.1 mole (24.83 g), DPD as a compound (b) in an amount of 0.1 mole (21.63 g) and tetra-iso-propoxytitanium as a catalyst in an amount of 22 millimoles (0.625 g) per 0.1 mole of DPD. After fitting a condenser to the flask, it was heated gradually from room temperature to 85° C. in an oil bath. After confirming the start of reflux by methanol generated at 85° C., reflux was continued at the same temperature for one hour. Thereafter, the condenser was removed and methanol was distilled away in vacuo at the same temperature. The degree of vacuum was increased gradually so as not to cause bumping. After reaching 3 Torr, vacuum drawing was continued for 2 hours at 80° C. with stirring, and finally the system was returned to normal pressure to conclude removal of methanol. After cooling the obtained polycondensate to room temperature, IRGACURE 369 (a product by Ciba-Geigy Corp.) was added as a photopolymerization initiator in an amount of 1 part by weight per 100 parts by weight of the obtained polycondensate and the mixture was passed through a 0.2 μm-mesh filter to obtain a photosensitive resin composition 1.

### [Preparation of Photosensitive Resin Composition 2]

To 100 parts by mass of the photosensitive resin composition 1, 10 parts by mass of polyethylene oxide bisphenol A dimethacrylate (Blemmer PDBE450 produced by Nippon Oil Corp.) was further added to prepare a photosensitive resin composition 2.

### [Preparation of Photosensitive Resin Composition 3]

The same procedure as used for the preparation of the photosensitive resin composition 1 was conducted except for a change in the amount of the materials supplied to the 500 ml egg-plant type flask, namely MEMO was supplied as a compound (a-1) in an amount of 0.02 moles (4.97 g), MEDMO as a compound (a-2) in an amount of 0.08 moles (18.59 g), DPD as a compound (b) in an amount of 0.1 mole (21.62 g) and tetra-iso-propoxytitanium as a catalyst in an amount of 22 millimoles (0.625 g). To 100 parts by mass of the obtained photosensitive resin composition, 10 parts by mass of polyethylene oxide bisphenol A dimethacrylate (Blemmer PDBE450 produced by Nippon Oil Corp.) was further added to obtain a photosensitive resin composition 3.

### Example 1

### Method for Producing a Microlens 1 Using a Mold

A microlens was produced by conducting the following steps sequentially.

### First Step:

To a nickel-made plastic lens mold having 100 openings measuring 30 μm in maximum depth and 100 μm in diameter, 5 drops of the photosensitive resin composition 1 were added by a dropper to fill the mold with the photosensitive resin composition 1. A non-alkali glass substrate (10 cm square, 0.7 mm thick) made by Coning Ltd., is used as the substrate, and the openings of the mold were pressed against the substrate.

### Second Step:

In a state where the photosensitive resin composition was held between the substrate and the mold, the assembly was irradiated with ultraviolet light onto the entire glass substrate with no mask by using CANON's near exposure device mirror projection aligner. The irradiation dose at the i-line wavelength (365 nm) was 400 mJ/cm².

### Third Step:

The mold was separated from the substrate.

### Fourth Step:

This substrate was heated in a curing oven under a nitrogen atmosphere at 200° C. for 2 hours to obtain a substrate having the microlens 1 attached thereto.

### Example 2

### Method for Producing a Microlens 2 Utilizing a Mold

The same procedure as practiced in Example 1 was conducted except that the first step was changed as described below.

### First Step:

A Coning's non-alkali glass substrate (10 cm square, 0.7 mm thick) was used as the substrate while MEMO was used as a silane compound. MEMO was diluted with an NMP solvent to a concentration of 5% by weight and spin coated on the substrate at 1,000 rpm for 20 seconds. With the silane compound-deposited side of the coated glass substrate facing upward, the substrate was heated on a hot plate at 120° C. for 5 minutes and then cooled. The thickness of the silane compound layer of the obtained substrate having the silane compound deposited thereon was 0.01 μm or less. To a nickel-made plastic lens mold having the openings, 5 drops of the photosensitive resin composition 1 were added by a dropper, filling the mold with the photosensitive resin composition 1. Then the openings of the mold were pressed against the silane compound-deposited side of the substrate.

### Example 3

### Method for Producing a Microlens 3 Utilizing a Mold

The same procedure as practiced in Example 2 was conducted except that the photosensitive resin composition 1 was replaced by the photosensitive resin composition 2.

### Example 4

### Method for Producing a Microlens 4 Utilizing a Mold

The same procedure as practiced in Example 1 was conducted except that the first step was changed as described below.

### First Step:

A Coning's non-alkali glass substrate (10 cm square, 0.7 mm thick) was used as the substrate and the photosensitive resin composition 3 was used as the composition containing a silane compound. After diluted with an NMP solvent to a concentration of 10% by weight, the photosensitive resin composition was spin coated on the substrate at 2,500 rpm for 30 seconds. With the photosensitive resin composition 3-deposited side of the coated glass substrate facing upward, it was heated on a hot plate at 120° C. for 5 minutes and then cooled. The thickness of the photosensitive resin composition 3 layer of the obtained substrate having the photosensitive resin composition 3 deposited thereon was 3 μm. To a nickel-made plastic lens mold having the openings, 5 drops of the photosensitive resin composition 3 were added by a dropper, filling the mold with the photosensitive resin composition 3. Then the openings of the mold were pressed against the photosensitive resin compound 3-deposited side of the substrate.

The plastic lenses could be made in Examples 1 to 4. In order to evaluate adhesion of the plastic lenses produced in Examples 1 to 4, the resin films 1 to 4 described below were formed and subjected to measurements.

In Example 1, the photosensitive resin composition 1 was spin coated on a glass substrate at 700 rpm for 30 seconds, and the obtained spin coating film of the photosensitive resin composition 1 was enveloped with a 0.3 mm thick PET film and passed through the second and fourth steps to form a resin film 1.

In Example 2, MEMO was used as a silane compound and, after diluted with an NMP solvent to a concentration of 5% by weight, spin coated on a glass substrate under the condition of 1,000 rpm and 20 seconds. With the silane compound-deposited side of the substrate facing upward, the substrate was heated on a hot plate at 120° C. for 5 minutes and then cooled. Thereafter, the photosensitive resin composition 1 was spin coated on the silane compound-deposited side of the substrate at 700 rpm for 30 seconds, and the obtained spin coated film of the photosensitive resin composition 1 was enveloped with a 0.3 mm thick PET film and further passed through the second and fourth steps to form a resin film 1.

In Example 3, MEMO was used as a silane compound and, after diluted with an NMP solvent to a 5 wt % concentration, spin coated on a glass substrate at 1,000 rpm for 20 seconds. With the silane compound-deposited side of the substrate facing upward, the substrate was heated on a hot plate at 120° C. for 5 minutes and then cooled. Thereafter, the photosensitive resin composition 2 was spin coated on the silane compound-deposited side of the substrate at 700 rpm for 30 seconds, and the obtained spin coated film of the photosensitive resin composition 1 was enveloped with a 0.3 mm thick PET film and further passed through the second and fourth steps to form a resin film 1.

In Example 4, the photosensitive resin composition 3 was used as the composition containing a silane compound and, after diluted with an NMP solvent to a 10 wt % concentration, spin coated on a substrate at 2,500 rpm for 30 seconds. With the photosensitive resin composition 3-deposited side of the substrate facing upward, the substrate was heated on a hot plate at 120° C. for 5 minutes and then cooled. Thereafter, the photosensitive resin composition 3 was spin coated on the silane compound-deposited side of the substrate at 700 rpm for 30 seconds, and the obtained spin coated film of the photosensitive resin composition 1 was enveloped with a 0.3 mm thick PET film and further passed through the second and fourth steps to form a resin film 1.

### <260° C. Reflow Resistance Test>

The plastic lens-deposited substrates obtained in Examples 1 to 4 were placed in an oven (Fine Oven DH-42 made by Yamato Scientific Co., Ltd.) set at 260° C., and baked in an air atmosphere for 5 minutes. The crack and separation of the lens before and after baking were visually observed for evaluation.

The results of evaluation were as shown below.

◯ (good): Neither crack nor separation takes place.

X (poor): Crack or separation takes place.

### <Adhesion Test>

After forming the resin films 1 to 4 corresponding to Examples 1 to 4 as described above, each film was cut by a cutter knife so that 1 mm wide 100 squares could be formed by using a cross-cut guide 1.0 for a cross-cut tape adhesion test (JIS K 5400). A cellophane tape was attached to the film from above, and then the tape was forced to separate. The number of the squares which remained on the substrate without adhering to the tape was counted to evaluate adhesion.

The results of evaluation were as shown below.

⊚ (excellent): All of the 100 squares remain on the substrate.
◯ (good): 60 to 99 squares remain on the substrate.
X (poor): 59 or fewer squares remain on the substrate.

### <Thermal Shock Resistance Test>

Each of the plastic lens-deposited substrates obtained in Examples 1 to 4 was placed in a thermal impact tester (Model TSE-10 made by Tabai Co., Ltd.) and subjected to a test in which the temperature was changed from and to −40° C. and 100° C. cyclically once every 30 minutes for a total of 500 cycles, and the presence or absence of cracks after 100, 300 and 500 cycles was observed to evaluate thermal shock resistance.

The results of evaluation were as shown below.

⊚ (excellent): No crack is formed even after 500 cycles.
◯ (good): Crack is formed after 300 cycles.
X (poor): Crack is formed after 100 cycles.

The results are shown in Table 1.

TABLE 1

| | Example 1 | Example 2 | Example 3 | Example 4 |
|---|---|---|---|---|
| 260° C. reflow | ◯ | ◯ | ◯ | ◯ |
| resistance test | | | | |
| Adhesion test | ◯ 70 | ⊚ 100 | ⊚ 100 | ⊚ 100 |
| | squares | squares | squares | squares |
| | remained | remained | remained | remained |
| Thermal shock | ◯ | ◯ | ⊚ | ⊚ |
| resistance test | | | | |

### Example 5

### Method for Producing a Microlens 5 Using Masks

The photosensitive resin composition 4 was diluted by adding and mixing 40% by weight of NMP, then dropped onto a silicon substrate and spin coated (2,500 rpm, 30 seconds). With the photosensitive resin composition side of the silicon substrate having the photosensitive resin composition 1 deposited thereon facing upward, the substrate was heated on a hot plate at 120° C. for 5 minutes. The thickness of the photosensitive resin composition layer after drying away NMP was 6 μm.

Three masks composed of the concentric circular patterns of plastic lens, i.e., the masks having the circular patterns (5 crosswise, 25 in total) of 2 μm, 4 μm and 6 μm, respectively, were provided in advance. The lowest light intensity causing saturation of resin film thickness retained after resin removal by development at this point was 90 mJ/cm², so that the mask having a 2 μm-diameter circular pattern was placed on the photosensitive resin composition layer and irradiated with ultraviolet light (using NSR 1755i7B made by Nikon Ltd.) at the light intensity of 90÷3=30 mJ/cm², and then the mask was removed. Then the mask having a 4 μm-diameter circular pattern was placed on the photosensitive resin composition layer by using an alignment mark and similarly irradiated, and then the mask was removed. Then the mask having a 6 μm-diameter circular pattern was placed on the photosensitive resin composition layer by using an alignment mark and similarly irradiated, and then the mask was removed.

The substrate obtained by 20-second rotational spray method was developed using cyclohexanone as a developer, and then the developed substrate was rinsed for 10 seconds using isopropyl alcohol as a rinsing fluid.

Step of heating at a temperature of 150° C. to 250° C. for 0.5 hour to 2 hours after development:

Heating was carried out in N₂ at 200° C. for 2 hours using a curing oven.

By following the above-described procedure, it was possible to obtain a high quality plastic lens with a height of 3 μm which never separates from its silicon substrate.

### INDUSTRIAL APPLICABILITY

The plastic lens produced according to the method of the present invention can be used as a lens for the solid-state image sensing devices and electronic part-integrated articles for which solder reflowing at 260° C. is required. Also, the method for producing a plastic lens according to the present invention is useful as an UV curing imprinting technique. For example, the present invention can be applied not only as a plastic lens producing method but also as a method for producing the optical elements for liquid crystal polarizers. The microlens producing method and the method for producing the optical elements for liquid crystal polarizers merely differ in size and type of the mold to be used and are essentially identical in process.

### BRIEF DESCRIPTION OF THE DRAWINGS

FIG. 1 is a schematic illustration of a plastic lens producing method using a mold according to the present invention, wherein:

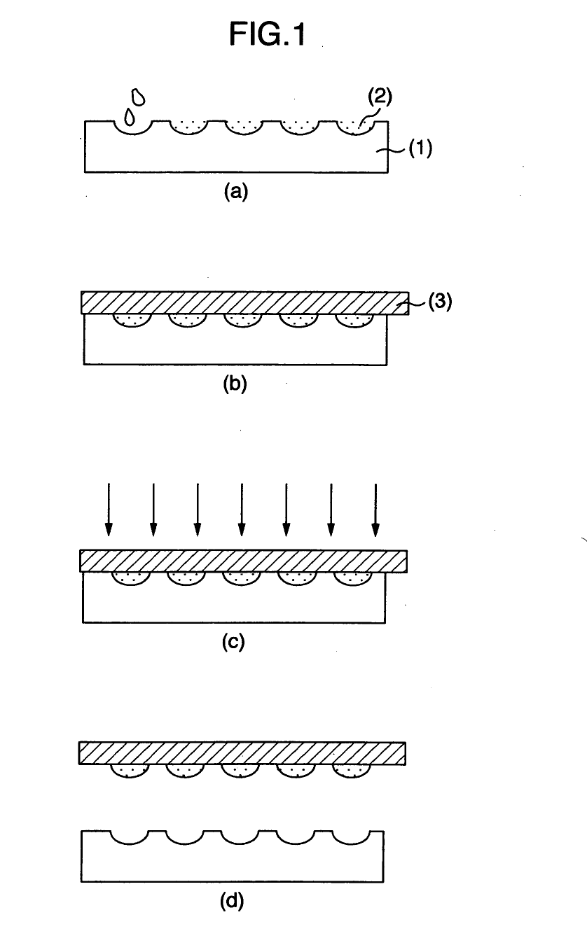

(a) shows a process of filling a plastic lens mold (1) having openings with the photosensitive resin composition (2);

(b) shows a process of pressing against a substrate (3) the openings of the mold filled with the photosensitive resin composition;

(c) shows a step of exposing the photosensitive resin composition; and

(d) shows a step of separating the plastic lens mold from the substrate;

FIG. 2 is a schematic illustration of a plastic lens producing method using the masks of the present invention, wherein (a) shows a step of obtaining a substrate having a photosensitive resin composition deposited thereon; (b-1) shows an example of exposure step; (b-2) shows another example of exposure step; (b-3) shows still another example of exposure step; and (b-4) is a top plan view of the masks for forming a lens; and (c) shows the substrate after development; and

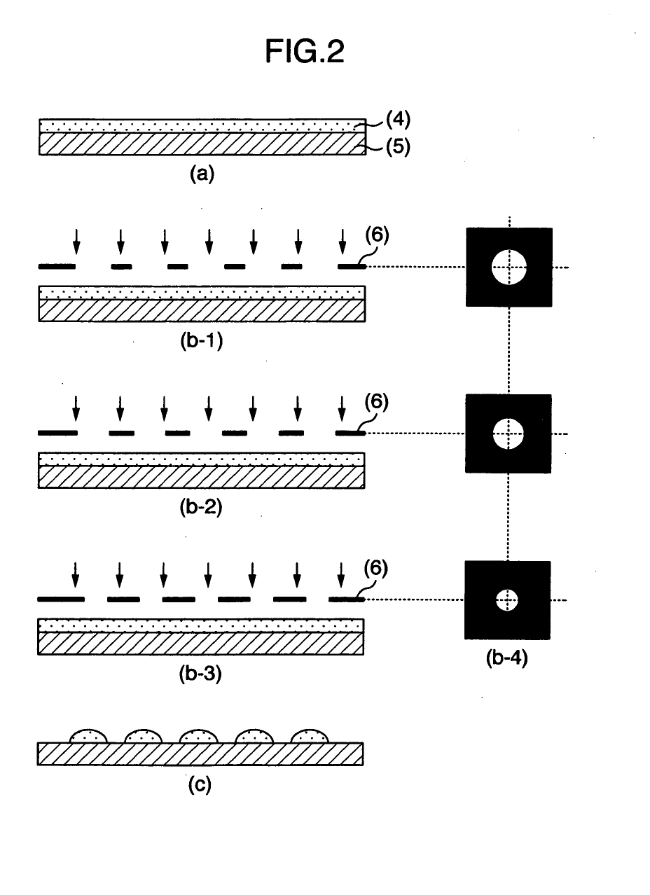

FIG. 3 is a diagram for determining the lowest light intensity causing saturation of resin film thickness retained after resin removal by development.

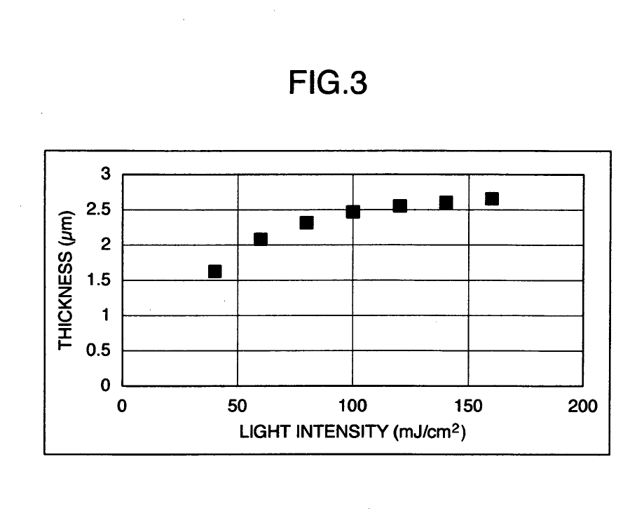

### DESCRIPTION OF REFERENCE NUMERALS

1 Mold for a plastic lens
2 Photosensitive resin composition
3 Substrate
4 Photosensitive resin composition
5 Substrate
6 Mask

1. A method for producing a plastic lens characterized in that a photosensitive resin composition containing a resin and a photopolymerization initiator is molded into a lens shape, the resin being obtained by mixing at least one compound (a) selected from the group consisting of —CO—C(CH₃O)₃—Si—(CH₂)₃—O—CO—C(CH₃)═CH₂, (CH₃O)₃—Si—(CH₂)₃—O—CO—CH═CH₂, (CH₃O)₃—Si—(CH₂)ₓ—CH═CH₂ (wherein X is 1 or 2), (CH₃O)₂—Si(CH₃)(CH₂)₃—O—CO—C(CH₃)═CH₂, (CH₃O)₂—Si(CH₃)(CH₂)₃—O—CO—CH═CH₂, and (CH₃O)₂—Si (CH₃)— (CH₂)ₓ—CH═CH₂ (wherein X is 1 or 2)
with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst.

2. A method for producing a plastic lens characterized by comprising a first step comprising a process of filling in a plastic lens mold having an opening(s) a photosensitive resin composition containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—Si—(CH₂)₃—O—CO—CH═CH₂, (CH₃O)₃—Si—(CH₂)ₓ—CH═CH₂ (wherein X is 1 or 2), (CH₃O)₂—Si(CH₃)(CH₂)₃—O—CO—C(CH₃)═CH₂, (CH₃O)₂—Si(CH₃)(CH₂)₃—O—CO—CH═CH₂, and (CH₃O)₂—Si(CH₃)—(CH₂)ₓ—CH═CH₂ (wherein X is 1 or 2)
with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst, and a process of pressing against a substrate the opening(s) of the mold filled with the photosensitive resin composition; a second step of exposing the photosensitive resin composition to light; a third step of separating the mold from the substrate; and a fourth step of heating the exposed photosensitive resin composition at a temperature of 150° C. to 250° C. for 0.5 hour to 2 hours, the first to fourth steps being carried out sequentially.

3. The method for producing a plastic lens according to claim 2 characterized in that the first step is a first step comprising a process of coating a substrate with a silane compound or a composition containing a silane compound to obtain a substrate having a silane compound deposited thereon, a process of filling in the plastic lens mold having an opening(s) the photosensitive resin composition containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—Si—(CH₂)₃—O—CO——CH═CH₂, (CH₃O)₃—Si—(CH₂)ₓ—CH═CH₂ (wherein X is 1 or 2), (CH₃O)₂—Si (CH₃)(CH₂)₃—O—CO—C(CH₃)═CH₂, (CH₃O)₂—Si(CH₃)(CH₂)₃—O—CO—CH═CH₂ and (CH₃O)₂—Si(CH₃)—(CH₂)ₓ—CH═CH₂ (wherein X is 1 or 2)
with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst, and a process of pressing the opening(s) of the mold filled with the photosensitive resin composition against the silane compound-deposited side of the substrate.

4. The method for producing a plastic lens according to claim 3 characterized in that the composition containing a silane compound is a composition same as the above photosensitive resin composition.

5. The method for producing a plastic lens according to claim 3 or 4 characterized in that the photosensitive resin composition is a photosensitive resin composition containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—Si—(CH₂)₃—O—CO—CH═CH₂ (CH₃O)₃—Si—(CH₂)ₓ—CH═CH₂ (wherein X is 1 or 2) with a compound (b) represented by (C₆H₅)₂—Si—(OH)₂ in a molar ratio of (a)/(b) of 60 mole %/40 mole % to 40 mole %/60 mole %, and then subjecting the mixture to polycondensation at a temperature of 40° C. to 150° C. for 0.1 to 10 hours in the presence of a catalyst.

6. The method for producing a plastic lens according to claim 3 or 4 characterized in that the photosensitive resin composition is a photosensitive resin composition containing a resin and a photopolymerization initiator, the resin being obtained by mixing at least one compound (a-1) selected from the group consisting of (CH₃O)₃—Si—(CH₂)₃—O—CO—C(CH₃)═CH₂, (CH₃O)₃—Si—(CH₂)₃—O—CO—CH═CH₂ and (CH₃O)₃—Si—(CH₂)ₓ—CH═CH₂ (wherein X is 1 or 2) and at least one compound (a-2) selected from the group consisting of (CH₃O)₂—Si(CH₃)(CH₂)₃—O—CO—C(CH₃)═CH₂, (CH₃O)₂—Si(CH₃)(CH₂)₃—O—CO—CH═CH₂, and (CH₃O)₂—Si(CH₃)—(CH₂)ₓ—CH═CH₂ (wherein X is 1 or 2) with a compound (b) represented by (C₆H₅)₂—Si—(OH)₂ in a proportion of 10 to 60 moles of the compound (a-1) and 40 to 90 moles of the compound (a-2) based on 100 moles of the compound (b), and then subjecting the mixture to polycondensation at a temperature of 40° C. to 150° C. for 0.1 to 10 hours in the presence of a catalyst.

7. A method for producing a plastic lens characterized by comprising a step of coating a substrate with a photosensitive resin composition containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—Si—(CH₂)₃—O—CO—CH═CH₂, and (CH₃O)₃—Si—(CH₂)ₓ—CH═CH₂ (wherein X is 1 or 2) with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst, and heating the coated substrate at 50 to 150° C. for one minute to 30 minutes to obtain a substrate having a photosensitive resin composition deposited thereon; a step of laying on the substrate one of a plurality of masks which form a concentric pattern when placed one on another, and then exposing it at a constant light intensity given by
(the lowest light intensity causing saturation of resin film thickness retained after resin removal by development)÷(number of masks),
and then removing the mask, a series of these operations being conducted once for each mask to thereby effect multiple exposure; a step of development; and a step of heating at a temperature of 150° C. to 250° C. for 0.5 hour to 2 hours, the steps being carried out sequentially.

8. A photosensitive resin composition for forming a plastic lens containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—Si—(CH₂)₃—O—CO—CH═CH₂ (CH₃O)₃—Si—(CH₂)ₓ—CH═CH₂ (wherein X is 1 or 2), (CH₃O)₂—Si(CH₃)(CH₂)₃—O—CO—C(CH₃)═CH₂, (CH₃O)₂—Si(CH₃)(CH₂)₃—O—CO—CH═CH₂, and (CH₃O)₂—Si(CH₃)—(CH₂)ₓ—CH═CH₂(wherein X is 1 or 2) with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst.

9. A plastic lens obtained by radiation curing a photosensitive resin composition containing a resin and a photopolymerization initiator, the resin being obtained by mixing at least one compound (a) selected from the group consisting of (CH₃O)₃—Si—(CH₂)₃—O—CO—C(CH₃)═CH₂, (CH₃O)₃—Si—(CH₂)₃—O—CO—CH═CH₂, (CH₃O)₃—Si—(CH₂)ₓ—CH═CH₂ (wherein X is 1 or 2), (CH₃O)₂—Si(CH₃)(CH₂)₃—O—CO—C(CH₃)═CH₂ (CH₃O)₂—Si (CH₃)(CH₂)₃—O—CO—CH═CH₂ and (CH₃O)₂—Si(CH₃)—(CH₂)ₓ—CH═CH₂ (wherein X is 1 or 2) with a compound (b) represented by (C₆H₅)₂—Si—(OH)₂ in a proportion of 50 to 150 moles of the compound (a) based on 100 moles of the compound (b), and then subjecting the mixture to polycondensation at a temperature of 40° C. to 150° C. for 0.1 to 10 hours in the presence of a catalyst.
